(19) United States
(12) Patent Application Publication
(10) Pub. No.: US 2015/0060257 A1
(43) Pub. Date: Mar. 5, 2015

(54) SWITCH SYSTEM

(71) Applicant: Honda Motor Co., Ltd., Tokyo (JP)

(72) Inventors: Takeyuki Suzuki, Wako-shi (JP); Masahiko Shimada, Wako-shi (JP); Hiroyuki Tanaka, Wako-shi (JP)

(21) Appl. No.: 14/474,822

(22) Filed: Sep. 2, 2014

(30) Foreign Application Priority Data
Sep. 2, 2013 (JP) 2013-181137
Sep. 30, 2013 (JP) 2013-204482

(51) Int. Cl. H03K 17/96

(52) U.S. Cl. CPC H03K 17/962; H03K 2217/960785; H03K 2217/960755; H03K 2217/96071
USPC 200/600

(57) ABSTRACT

A switch system that can be accurately operated even when disposed in a narrow area is provided. In this switch system, an operator touches an operation surface of a switch with a finger, a change in electrostatic capacitance caused by the touch is sensed, and the movement of the finger of the operator is detected. The operation surface of the switch is formed into concavities or convexities.

### FIELD OF THE INVENTION

The present invention relates to a switch system having touch switches.

### BACKGROUND OF THE INVENTION

There are known switch systems in which an operator touches an operation surface with a finger, and a charge in electrostatic capacitance caused by the touch is sensed. For example, a switch system is attached to a spoke of a steering wheel in order to operate an onboard instrument. The technology disclosed in JP-A 2009-298285 is an example of this type of conventional technology.

In a vehicle steering switch such as the one in JP-A 2009-298985, an operation unit comprising a touch switch capable of gesture operations such as a swipe operation is attached to a spoke.

An operator can operate any desired onboard instrument by touching the operation surface of the touch switch with a finger. A car navigation system is a possible example of an onboard instrument.

However, when the switch is disposed in a narrow area such as a spoke, there is a risk of accidentally operating a different switch than the switch necessary for the operation.

### SUMMARY OF THE INVENTION

An object of the present invention is to provide a switch system that can be operated accurately even when disposed in a narrow area.

According to the present invention, there is provided a switch system wherein an operator touches an operation surface of a switch with a finger, a change in electrostatic capacitance caused by the touch is sensed, and movement of the finger of the operator is detected, and wherein the operation surface of the switch is formed into concavities or convexities.

In the present invention as explained above, the operation surface of the switch is formed into concavities or convexities. Due to the operation surface being formed into concavities or convexities, the operator can easily recognize that he is touching the operation surface of the switch. The operator can thereby be prevented from touching the finger to an incorrect area, and the operator can accurately perform any desired operation.

Preferably, the areas formed into concavities or convexities are formed over the entire range in which the operator can perform operations.

Specifically, the operator performs a switch sliding operation in the range of the areas formed into concavities or convexities. The accuracy of operation can be further secured by clarifying the range in which the operation can be performed.

Preferably, a general surface at the peripheral edge of the operation surface of the switch is a smooth surface.

The operation surface is formed into concavities or convexities, while the general surface unrelated to operations is formed into a smooth surface. The design of the switch can be improved due to the three-dimensional operation surface and the two-dimensional general surface being continuous.

Preferably, the operation surface of the switch is disposed on a spoke of a vehicle steering wheel; and the areas of the concavities or convexities are formed along an arc of a preset designated radius centered around an area in the vehicle steering wheel that is touched by the base of the thumb of operator when gripping a rim.

Specifically, the areas of the concavities or convexities and the switch are disposed so as to be aligned along the trajectory of the thumb of the operator gripping the rim. The operator can thereby operate the switch with natural finger movements. Specifically, the operability of the switch can be improved by employing this configuration.

Preferably, the operation surface of the switch is disposed on a substantially T-shaped spoke of the vehicle steering wheel, which comprises a rim and the spoke, the spoke being formed integrally on the inner periphery of the rim; the vehicle steering wheel is configured so that the operator grips the proximity of a point of intersection between the rim and a laterally extending side of the substantially T-shaped spoke; and a line through the areas formed into the concavities or convexities intersects a line at an incline so as progress outward from the bottom to the top, the line extending perpendicular to the laterally extending side.

Specifically, the areas of the concavities or convexities and the switch are disposed so as to be aligned along the trajectory of the thumb of the operator gripping the rim. The operator can thereby operate the switch with natural finger movements. Specifically, the operability of the switch can be improved by employing this configuration.

Preferably, the switch is a first switch; the spoke also has a second switch; the second switch is disposed in an area closer to the rim than the first switch; and the switch system has a control unit for assessing that only a contact signal of the first switch has been detected when contact signals are simultaneously received from both the first switch and the second switch.

The second switch is disposed in a position closer to the rim than the first switch. When the first switch is operated while the rim is gripped, there is a risk that the second switch will be mistakenly touched simultaneously. When both the first and second switches are touched simultaneously, the instrument can be controlled as intended by the operator by performing control so that the operation of the second switch is invalidated. The operability of the switches is thereby further improved.

Preferably, the operation surface of the first switch is tilted to the front in the vehicle body relative to the operation surface of the second switch so as to move away from the finger of the operator.

The operation surface of the first switch and the operation surface of the second switch are disposed along different directions. Faulty operations can thereby be suppressed, and the accuracy of operation can be further improved.

Preferably, a backlight for illuminating the operation surface of the switch is provided in the proximity of the switch; and the backlight is turned on by the detection of contact on the switch by the operator.

The area where the switch is disposed is made visually clear. The accuracy of operating the operation unit can thereby be further improved.

Preferably, the switch system is attached to a steering wheel; the steering wheel comprises a rim for steering the vehicle and a spoke formed integrally on the inner peripheral surface of the rim; the operation surface is positioned in an area within the spoke allowing operation while the rim is gripped; and the operation surface is positioned farther forward in the vehicle body than a plane fanning out from an area where the distal end of the thumb of the operator in a normal driving posture touches the rim; the axis being a direction orthogonal to the plane of the steering wheel; and the center being the area touched by the ball of the thumb of the operator when the operator grips the rim.

There is a high height to the operation surface from a line drawn parallel to the operation surface from the apex of the rim, in alignment with the orientation of the thumb while the steering handle is being gripped normally. The operation unit can thereby be swiped by the thumb while the rim is gripped. When this operation is performed, the operation is with the thumb upright in accordance with the forward-retreating formation. The contact surface area of the thumb on the operation unit can be reduced because the distal end of the thumb is in contact with the operation surface. Due to the smaller contact surface area, mistaken contact on switches in the proximity of the area being operated can be suppressed. The accuracy of operating the operation unit can thereby be improved. Additionally, because the thumb operates the unit while upright, the operation is performed more easily. Operation with the thumb is also made easier because the base of the thumb (ball of the thin b) is in contact with the rim.

Preferably, the operation surface is inclined forward in the vehicle body from the outer peripheral edge of the rim toward the center.

The operation with a more natural posture is thereby made possible.

Preferably, the operation surface is positioned in a location where the operation surface can be operated by the thumb of the operator while the bail of the thumb is in contact with the rim.

Therefore, operation with a more natural posture is made possible because the operation surface is disposed within the length of the thumb.

### BRIEF DESCRIPTION OF THE DRAWINGS

Several preferred embodiments of the present invention will be described in detail hereinafter with reference to the accompanying drawings, in which:

FIG. 1 is a schematic view of a vehicle equipped with the switch system according to the first embodiment of the present invention;

FIG. 2 is a cross-sectional view along line 2-2 of FIG. 1;

FIG. 3 is a cross-sectional view along line 3-3 of FIG. 1;

FIGS. 4A and 4B are enlarged views of the operation unit shown in FIG. 1;

FIG. 5 is a flowchart for describing the relationship between the first switch and the second switch shown in FIG. 1;

FIG. 6 illustrates the effect of the vehicle steering switch shown in FIG. 1;

FIG. 7 is a cross-sectional view of an operation unit equipped with the switch system of the second embodiment of the present invention;

FIG. 8 is a front view of an operation surface of the switch system of the third embodiment of the present invention; and

FIGS. 9A and 9B illustrate an operation surface of the switch system of the fourth embodiment of the present invention.

### DETAILED DESCRIPTION OF THE PREFERRED EMBODIMENTS

Embodiments of the present invention are described below with reference to the accompanying drawings. In the drawings, the terms “left” and “right” refer to the left and right referencing an occupant of the vehicle, and the terms “front” and “back” refer to the front and back referencing the traveling direction of the vehicle. Fr in the drawings indicates the front, Rr indicates the back, Ce indicates the vehicle-width middle, Up indicates up, and Dn indicates down.

### First Embodiment

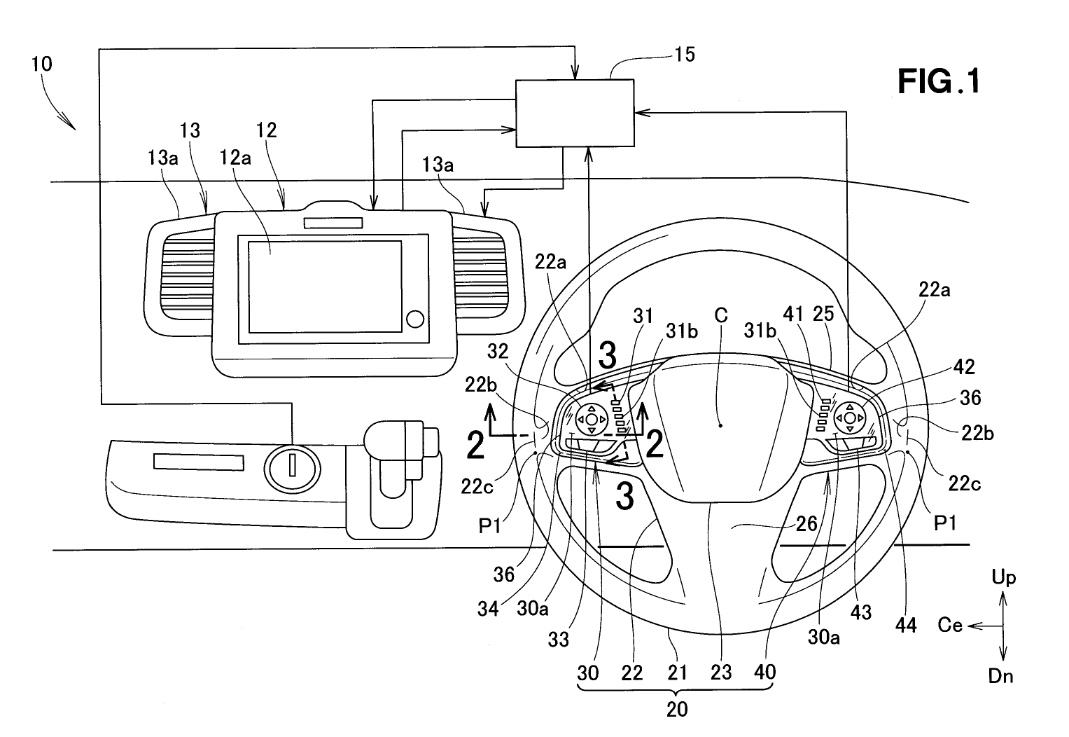

As shown in FIG. 1, a vehicle steering wheel 20 (referred to below simply as the “steering wheel 20”) for steering a vehicle 10 is provided in the front inside the passenger compartment.

A monitor 12a of an audio device 12 (an onboard instrument 12) is provided in the proximity of the steering wheel 20, and two blower vents 13a, 13a of an air-conditioning device 13 (an onboard instrument 13) are provided on either side of the monitor 12a.

The monitor 12a serves as a monitor for a car navigation system.

The audio device 12 and the air-conditioning device 13 have a control unit 15, and the level of noise and the rate of air blown are controlled by the control unit 15. Only one control unit 15 is conceptually shown. Specifically, two or more control units 15 can be disposed in any desired locations.

The steering wheel 20 is composed of a rim 21 that is substantially circular and can be steered by a vehicle occupant, a substantially T-shaped spoke 22 formed integrally on the inner peripheral surface of the rim 21, a horn switch cover 23 attached to the middle of the spoke 22 and placed over a horn switch, a first operation unit 30 (an operation unit 30) provided adjacent to the left side of the horn switch cover 23 and used for operating the audio device 12, and a second operation unit 40 (an operation unit 40) provided adjacent to the right side of the horn switch cover 23 and used for operating the air-conditioning device 13.

The first operation unit 30, the horn switch cover 23, and the second operation unit 40 are disposed along a straight line. The first operation unit 30, the horn switch cover 23, and the second operation unit 40 correspond to a laterally extending side 25 of the substantially T-shaped spoke 22.

The horn switch cover 23 is disposed in the center C of the rim 21.

The first operation unit 30 and the second operation unit 40 are both hooked up to the control unit 15.

The point of intersection between the laterally extending side 25 of the spoke 22 and a longitudinally extending side 26 coincides with the center C of the rim 21.

The first operation unit 30 is an area for performing operations of the audio device 12. When an operator operates the first operation unit 30, an operation signal is generated. Based on the operation signal, the control unit 15 changes a song selection or the sound level.

The second operation unit 40 is an area for performing operations of the air-conditioning device 13. When an operator operates the second operation unit 40, an operation signal is generated. Based on the operation signal, the control unit 15 switches between heating and cooling or changes the temperature.

The first operation unit 30 and the second operation unit 40 have the same essential configuration, and the first operation unit 30 primarily is described below as an example.

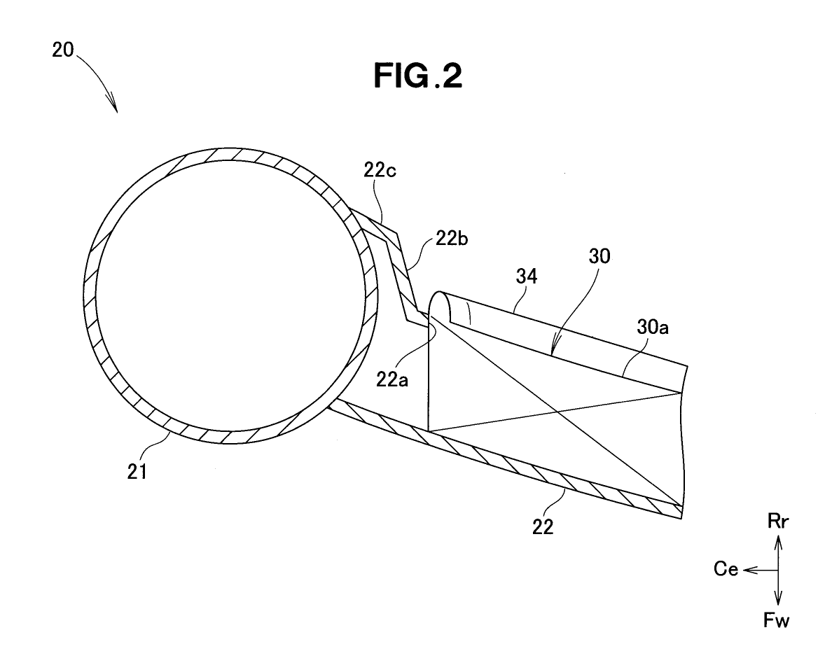

As shown in FIG. 2, a pipe-shaped material is used as the rim 21. The spoke 22 extends from the inner periphery of the rim 21 toward the center C of the rim 21 (see FIG. 1) at a slight, forward incline. The spoke 22 is directly connected to the inner periphery of the rim 21.

An opening 22a is formed in the spoke 22. The first operation unit 30, consolidated into a unit, is embedded in the opening 22a.

The opening 22a is formed toward the driver seat. An operation surface 30a of the first operation unit 30 is disposed facing the driver seat. The operation surface 30a, together with the spoke 22, is inclined slightly forward toward the center of the rim 21.

An extending part 22b that extends forward is formed in the end part of the spoke 22. Due to the formation of the extending part 22b, a proximal end part 22c of the spoke 22 and the peripheral edge area of the opening 22a are formed in the shape of a step. The end part of the spoke 22 can also be referred to as the border between the rim 21 and the spoke 22. Specifically, the border between the rim 21 and the spoke 22 is formed into the shape of a step so that with the rim 21 as a reference, the spoke 22 (at least the area where the first operation unit 30 is attached) separates forward.

Other options of a configuration in which the border between the rim 21 and the spoke 22 is formed into a step shape include bending the spoke 22, as well as changing the shape of part of the rim 21, and placing a separate member for forming a step in between the rim 21 and the spoke 22.

Returning to FIG. 1, a first switch 31 (a switch 31) is disposed in an area within the first operation unit 30 that is in the proximity of the horn switch cover 23. Specifically, the first switch 31 (the switch 31) is disposed in the side near the center of the rim 21. A second switch 32 is disposed adjacent to the first switch 31, on the side near the rim 21. A third switch 33 is disposed below the second switch 32.

The first to third switches 31 to 33 are electrostatic capacitance switches that detect touching by an operator, for example.

Touch switches other than those of the electrostatic capacitance type can also be employed as the first to third switches 31 to 33.

The first to third switches 31 to 33 are disposed within an area enclosed by a frame 34. A distal end of the frame 34 protrudes nearer to the operator than the operation surface 30a of the first operation unit 30.

First to third switches 41 to 43 are disposed in the second operation unit 40 as well, similar to the first operation unit 30.

For example, a first switch 41 (a switch 41) is operated when a temperature setting is adjusted, a second switch 42 is operated when an air-blowing mode is selected, and a third switch 43 is operated when cooling or heating is selected.

The switch system in the present invention is composed of either the first operation unit 30 and the control unit 15, or the second operation unit 40 and the control unit 15.

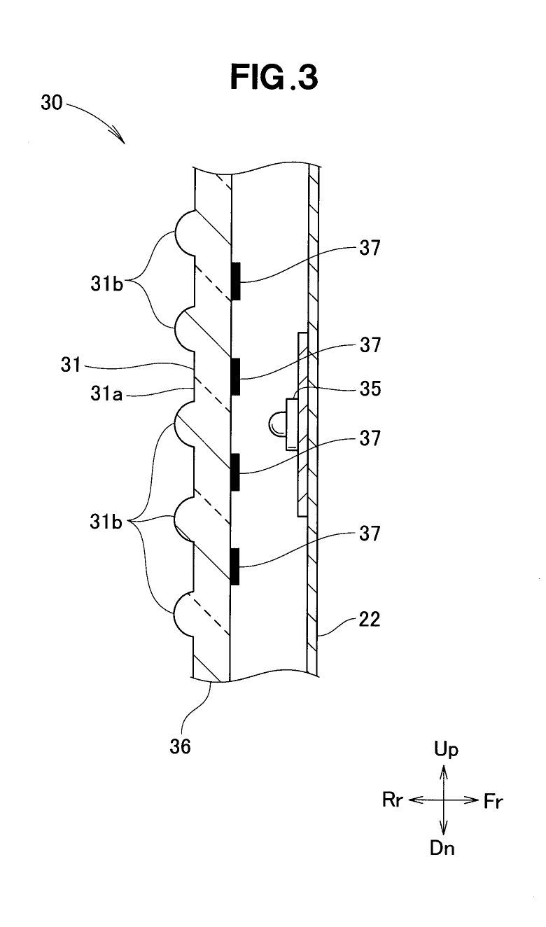

Referring to FIG. 3, an LED backlight 35 is installed in the first operation unit 30. The backlight 35 is covered by a plastic operation panel 36. An operation surface 31a of the first switch 31 is formed in part of the operation panel 36.

A plurality of convexities 31b is formed in the operation surface 31a of the first switch 31. The convexities 31b can be formed integrally in the operation panel 36 by extrusion molding. The convexities 31b are formed over the entire operation surface 31a of the first switch 31. Specifically, the entire operation surface 31a of the first switch 31 is formed into convex shapes.

Blinder members 37 are affixed to the back surface of the operation surface 31a of the first switch 31, in areas corresponding to the spaces between the convexities 31b. The convexities 31b alone thereby appear to be lit up when the backlight 35 is turned on. Specifically, due to the blinder members 37 being affixed in areas corresponding to the spaces between the convexities 31b, the convexities 31b are emphasized and the outward appearance of the first operation unit 30 can be improved.

The backlight 35 is turned on by detection of contact of the firs switch 31 by the operator. After being turned on, the backlight 35 is turned off by the elapse of a designated period. These controls are performed by the control unit 15 (see FIG. 1). The area where the first switch 31 is disposed is made visually clear by the backlight 35 turning on. The accuracy of operating the first operation unit 30 can thereby be improved.

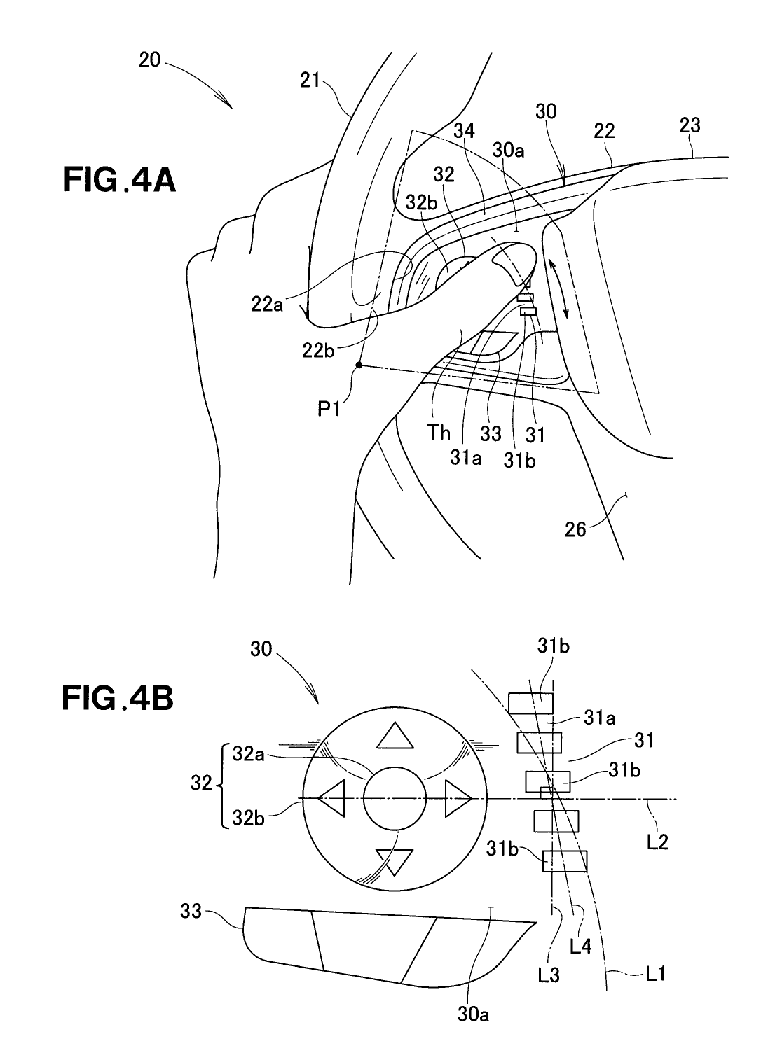

Referring to FIG. 4A, the general surface 30a at the peripheral edge of the operation surface 31a is a smooth surface. The first operation unit 30 is operated by the thumb Th of the left hand gripping the rim 21.

While gripping the rim 21, the operator performs an operation (a swipe operation) of rotating the thumb Th about the base P1 of the thumb. The area shown by the imaginary lines is the area in which the thumb Th can move while extended straight. Specifically, the area shown by the imaginary lines is the area in which the swipe operation can be performed. This area of possible movement supposes that the thumb is that of the average adult male (American). The operation surface 30a is formed underneath this area.

Referring to FIG. 4B as well, the first switch 31 is a switch for adjusting the sound level, and is disposed along a substantially vertical direction. When adjusting the sound level, the operator slides the thumb Th up and down on the operation surface 31a of the first switch 31. The thumb Th is slid upward to raise the sound level, and the thumb Th is slid downward to lower the sound level.

More specifically, the thumb Th of the operator gripping the rim 21 is slid so as to move in a substantially arcuate trajectory L1 about the base area P1 of the thumb Th. The first switch 31 is disposed substantially in alignment with the trajectory L1. Specifically, the first switch 31 is disposed in a position overlapping the trajectory L1 of the thumb Th of the operator.

The vehicular steering wheel 20 is configured so that the operator grips the proximities of the points of intersection between the rim and the laterally extending side 25 of the substantially T-shaped spoke. A line L4 through the convexities 31b intersects a line L3 extending perpendicular to the laterally extending side 25 (L2), and does so at an incline so as progress outward from the bottom to the top.

The convexities 31b are formed along a preset arc L1 of a designated radius, centered about the area P1 in the steering wheel 20 that is adjoined by the base of the thumb Th of the operator gripping the rim 21. The operator can thereby operate the first switch 31 by natural finger movements. Specifically, the operability of the first switch 31 can be improved by employing this configuration.

The convexities 31b are formed in the operation surface 31a of the first switch 31. Due to the formation of the convexities 31b, the operator can easily recognize that he is touching the operation surface 31a of the first switch 31. The operator can thereby be prevented from touching the thumb Th to an incorrect area, and the operator can accurately perform any desired operation.

The convexities 31b are formed over the entire area in which the swipe operation can be performed. Specifically, the operator performs the swipe operation of the first switch 31 within the range of the area where the convexities 31b are formed. The accuracy of operation can be further secured by clarifying the range in which the operation can be performed.

Furthermore, the general surface 30a at the peripheral edge of the operation surface 31a of the first switch 31 is a smooth surface. The convexities 31b are formed in the operation surface 31a, while the general surface 30a unrelated to operations is formed into a smooth surface. The design of the first switch 31 (the first operation unit 30) can be improved due to the three-dimensional operation surface 31a and the two-dimensional general surface 30a being continuous.

The second switch 32 is formed in the shape of a double circle, wherein an enter key 32a is disposed in the middle and a directional key 32b is disposed so as to enclose the enter key 32a. Furthermore, the second switch 32 is formed into a bowl shape so that the center of the double circle is the deepest. Faulty operation of the switches 31 to 33 can be further minimized by forming concavities and convexities in the second switch 32. Specifically, the accuracy of operating the first operation unit 30 can be improved.

The second switch 32 is used to select a song title, for example. To select any desired song, the operator uses the directional key 32b to select a song title shown on the monitor 12a (see FIG. 1), and uses the enter key 32a to choose the song. The operator then uses the thumb Th to press the enter key 32a or the directional key 32b.

The third switch 33, which is disposed along the direction in which the spoke 22 extends, is a switch for making music or radio selections, for example. Pressing the desired key switches between music, AM radio, and FM radio. The third switch 33 can also be operated by the thumb Th of the operator.

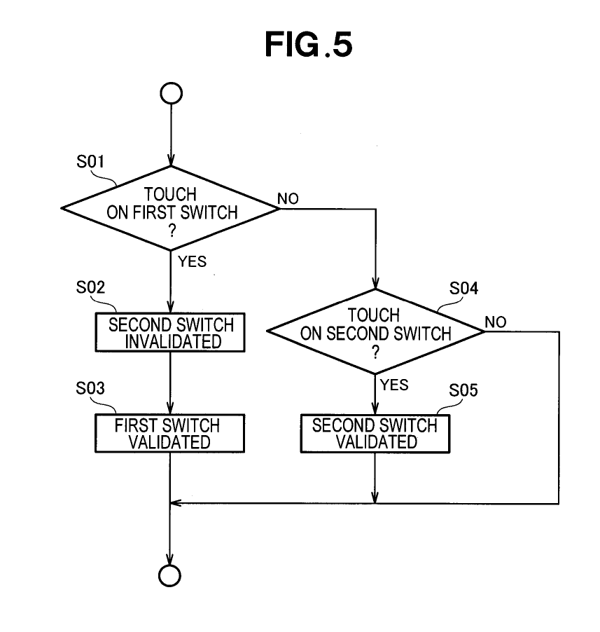

Referring to FIGS. 1 and 5, in step S01, the control unit 15 assesses whether or not the operator is touching the first switch 31. More specifically, the control unit 15 assesses that the operator is touching the first switch 31 by receiving a detection signal from the first switch 31.

When the operator is touching the first switch 31, the sequence advances to step S02. In step S02, the control unit 15 invalidates the second switch 32. Specifically, control of the audio device 12 based on an operation signal of the second switch 32 is not performed while the operator is touching the first switch 31, even if the operator touches the second switch 32. Specifically, when the control unit 15 simultaneously receives a contact signal from both the first switch 31 and the second switch 32, the control unit 15 detects only the contact signals of the first switch 31.

Referring again to FIG. 4A, the second switch 32 is disposed in a position closer to the rim 21 than the first switch 31. There is a risk that when the operator intends to operate the first switch 31 while gripping the rim 21, the operator will accidentally touch the second switch 32 at the same time. When the operator simultaneously touches both the first and second switches 31, 32, a control is performed so that the operation of the second switch 32 is invalid, whereby the audio device 12 can be controlled as intended by the operator. The operability of the switches is thereby further improved.

Returning to FIGS. 5 and 1, in step S03, the control unit 15 validates the first switch 31. Specifically, an electric signal is sent from the control unit 15 to the first switch 31 on the basis of the operation performed by the operator. Based on this electric signal, the control unit 15 controls the audio device 12. The order of step S02 and step S03 may be reversed.

When contact on the first switch 31 is not detected in step S01, the sequence advances to step S04. In step S04, the control unit 15 assesses whether or not the operator is touching the second switch 32. More specifically, the control unit 15 assesses whether or not the operator is touching the second switch 32 by receiving a detection signal from the second switch 32.

The sequence advances to step S05 when the operator is touching the second switch 32. In step S05, the control unit 15 validates the second switch 32. Specifically, an electric signal is sent to the control unit 15 from the second switch 32 on the basis of the operation performed by the operator. Based on this electric signal, the control unit 15 controls the audio device 12.

The sequence ends when contact on the second switch 32 is not detected in step S04.

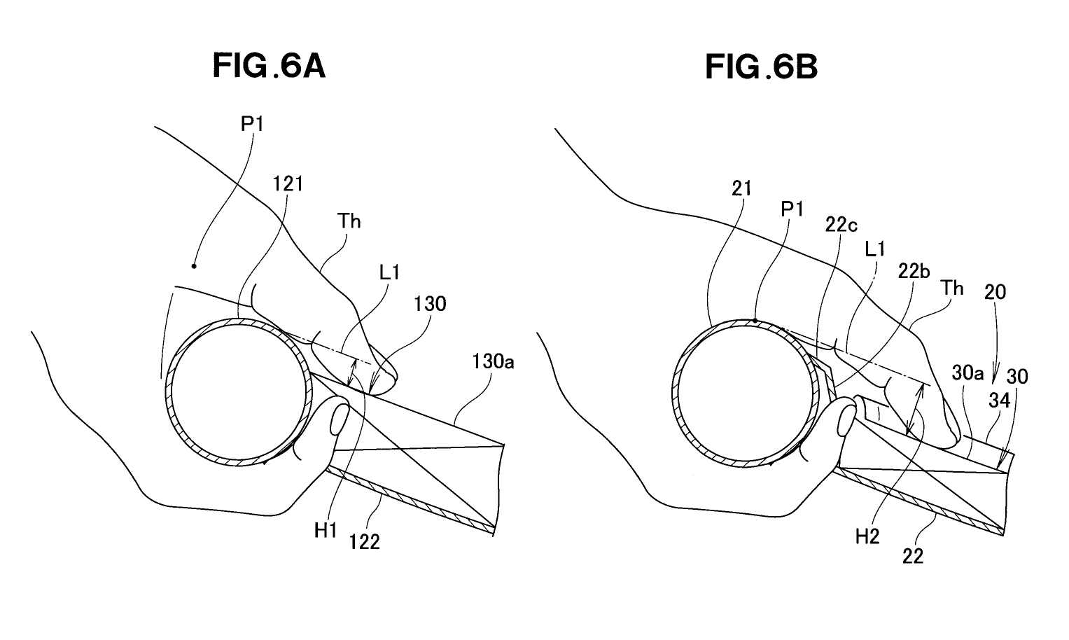

Referring to the conventional example shown in FIG. 6A, when a spoke 122 extends in a straight line from a rim 121, the base P1 of the thumb Th (the ball of the thumb) is separated from the rim 121. Because the center of the trajectory of the thumb Th is separated from the rim 121, it is difficult for the thumb Th to perform the swipe operation. The operational sensation is also poor when the thumb Th is laid down.

Furthermore, the thumb Th extends straight. Therefore, the trunk part of the thumb Th contacts an operation surface 130a of an operation unit 130. The surface area of the part of the thumb Th making contact becomes larger, and there is a risk of mistaken contact on a switch in the proximity of the area being operated. Specifically, there is a low height H1 to the operation surface 130a from a line L1 drawn parallel to the operation surface 130a from the apex of the rim 121. The surface area of the thumb Th in contact with the operation surface 130a thereby becomes larger. Due to the larger contact surface area, it is difficult to detect the operation and faulty operations are likely.

Referring to the embodiment shown in FIG. 6B, the border between the rim 21 and the spoke 22 in the present invention is formed in the shape of a step so that the spoke 22 separates forward with the rim 21 as a reference. Therefore, there is a high height H1 to the operation surface 30a from a line L1 drawn parallel to the operation surface 30a from the apex of the rim 21. When the first operation unit 30 is operated by the thumb Th while the rim 21 is gripped, the operation is with the thumb Th upright in accordance with the step shape formed by the border. The contact surface area of the thumb Th on the first operation unit 30 can be reduced because the distal end of the thumb Th is in contact with the operation surface 30a. Due to the smaller contact surface area, mistaken contact on switches in the proximity of the area being operated can be suppressed. The accuracy of operating the first operation unit 30 can thereby be improved.

Additionally, because the thumb Th operates the unit while upright, the operation is performed more easily. Operation with the thumb Th is also made easier because the base P1 of the thumb Th is in contact with the rim 21.

Furthermore, the peripheral edge of the operation surface 30a is enclosed by the frame 34, and the distal end of the frame 34 protrudes nearer to the operator than the operation surface 30a. Therefore, the thumb Th operates the unit while upright in accordance with the need to avoid the distal end of the frame 34 when the first operation unit 30 is operated by the thumb Th while the rim 21 is gripped. The accuracy of operating the first operation unit 30 can thereby be further improved.

Furthermore, the operation surface 30a inclines forward in the vehicle body toward the center of the rim 21 from the outer peripheral surface. The operation surface can thereby be operated will a more natural posture.

Furthermore, the operation surface 30a is positioned in a location where it can be operated by the thumb Th of the vehicle occupant while the ball of the thumb is in contact with the rim 21. The operation surface 30a can be operated with a more natural posture because it is disposed within the length of the thumb Th.

### Second Embodiment

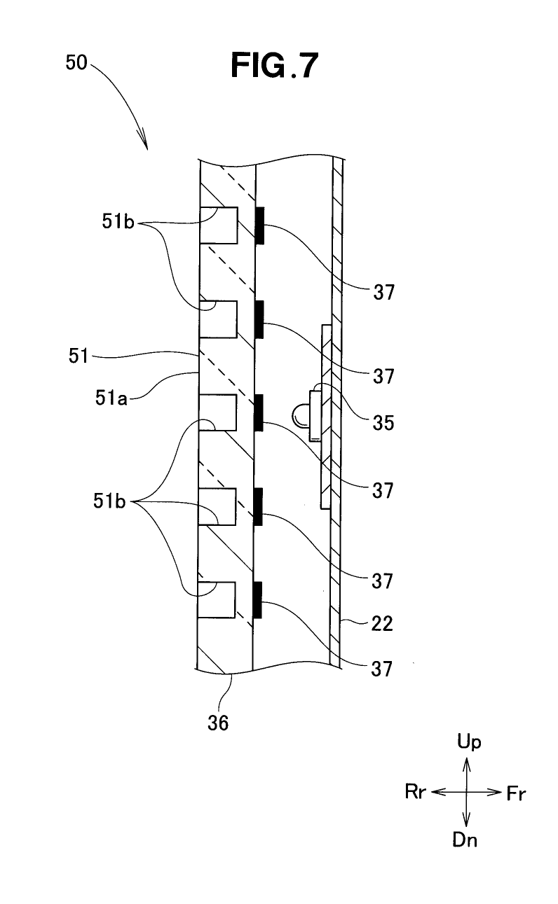

Next, a second embodiment of the present invention is described with reference to the drawings. FIG. 7 shows a cross-sectional configuration of an operation unit equipped with the switch system of the second embodiment. FIG. 7 corresponds to FIG. 3 described above. Elements common to the first embodiment are denoted by the same symbols, and detailed descriptions thereof are omitted.

As shown in FIG. 7, a plurality of concavities 51b are formed in an operation surface 51a. Specifically, an operation surface 51a of a first switch 51 is formed into a concave shape. The concavities 51b are formed over the entire operation surface 51a of the first switch 51.

Blinder members 37 are affixed to the back surface of the operation surface 51a of the first switch 51, in areas corresponding to the concavities 51b. The areas between the concavities 51b thereby appear to be lit up when a backlight 35 is turned on. Specifically, due to the blinder members 37 being affixed in areas corresponding to the concavities 51b, the areas between the concavities 51b are emphasized and the outward appearance of the first operation unit 50 can be improved. The other designated effects of the present invention can still be achieved when such a configuration is used.

### Third Embodiment

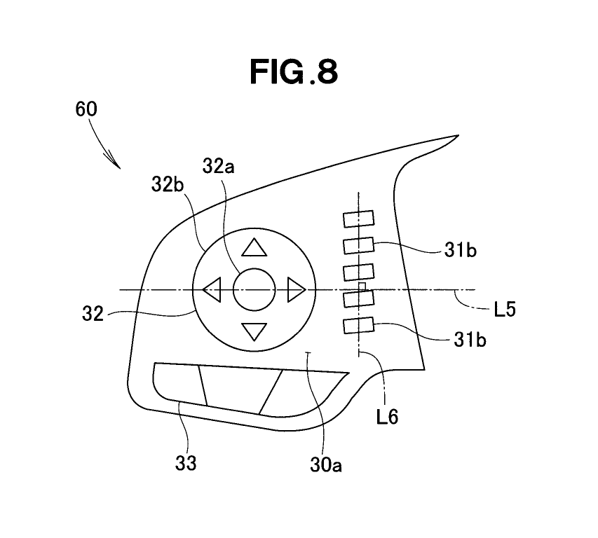

Next, a third embodiment of the present invention is described with reference to the drawings. FIG. 8 shows an operation surface of a switch system of the third embodiment. Elements common to the first embodiment or the second embodiment are denoted by the same symbols, and detailed descriptions thereof are omitted.

Referring to FIG. 8, a plurality of convexities 31b are formed in a first operation unit 60. These convexities 31b are formed along a line L6 that is orthogonal to a line L5 from the center C of the rim (see FIG. 1) to the rim 21 (see FIG. 1). These convexities 31b are formed at a slant relative to the line L6. The designated effects of the present invention can still be obtained in such a case.

### Fourth Embodiment

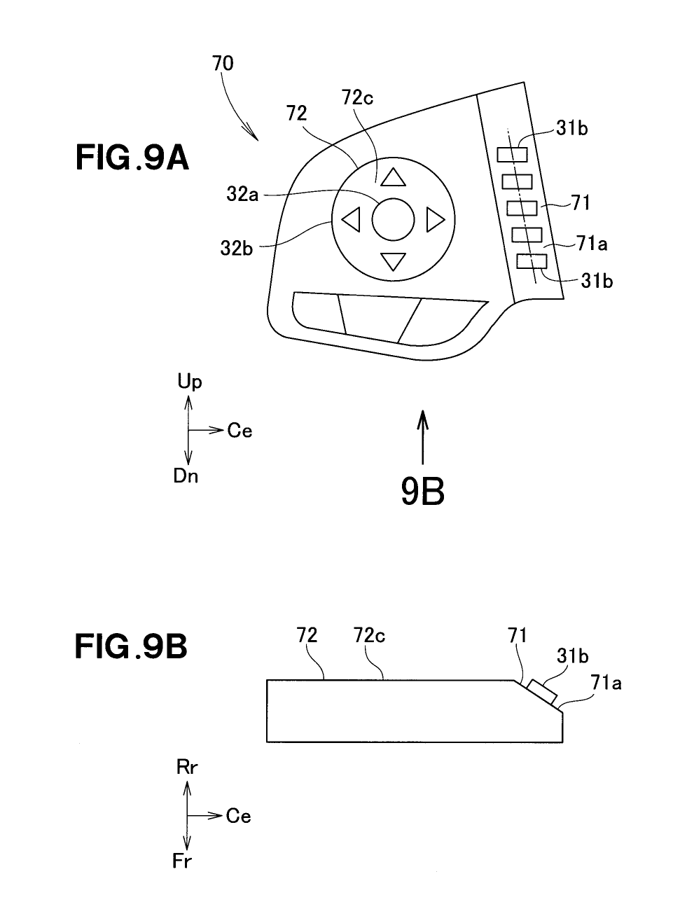

Next, a fourth embodiment of the present invention is described with reference to the drawings. FIGS. 9A and 9B show an operation surface of a switch system of the fourth embodiment. Elements common to the first embodiment, the second embodiment, or the third embodiment are denoted by the same symbols, and detailed descriptions thereof are omitted.

Referring to FIGS. 9A and 9B, FIG. 9B is a view from the arrow 9B in FIG. 9A. An operation surface 71a of a first switch 71 of a first operation unit 70 is inclined forward in the vehicle body relative to an operation surface 72c of a second switch 72 so as to move away from the finger of the operator. The designated effects of the present invention can still be obtained in such a case.

Furthermore, the operation surface 71a of the first switch 71 and the operation surface 72c of the second switch 72 are disposed along different directions. It is thereby possible to suppress faulty operations and to further improve the accuracy of operation.

A case of operating an audio device was used as an example to describe the switch system of the present invention, but the switch system can also be used to operate other onboard instruments such as car navigation systems. Specifically, the onboard instrument is not limited to these examples as long as the object of the present invention can be achieved. Different embodiments can also be combined as appropriate as long as the actions and effects of the present invention are achieved.

An average adult male was assumed as the vehicle occupant in the present invention. The size of the hand and the position of the ball of the thumb were also assumed to be those of the average adult male.

The steering wheel in the present invention was presented in an embodiment in which the border between the rim 21 and the spoke 22 was formed in the shape of a step such that the spoke 22 separated forward with the rim 21 as a reference, but the border need not be formed in the shape of a step and may be formed in the shape of an inclined surface.

Obviously, various minor changes and modifications of the present invention are possible in light of the above teaching. It is therefore to be understood that within the scope of the appended claims the invention may be practiced otherwise than as specifically described.

What is claimed is:

1. A switch system,
wherein an operator touches an operation surface of a switch with a finger, a change in electrostatic capacitance caused by the touch is sensed, and movement of the finger of the operator is detected, and the operation surface of the switch is formed into concavities or convexities.

2. The switch system of claim 1, wherein the areas formed into concavities or convexities are formed over the entire range in which the operator can perform operations.

3. The switch system of claim 1, wherein a general surface at the peripheral edge of the operation surface is a smooth surface.

4. The switch system of claim 1, wherein:
the operation surface is disposed on a spoke of a vehicle steering wheel; and
the areas of the concavities or convexities are formed along an arc of a preset designated radius centered around an area in the vehicle steering wheel that is touched by the base of the thumb of the operator when gripping a rim.

5. The switch system of claim 1, wherein:
the operation surface is disposed on a substantially T-shaped spoke of the vehicle steering wheel, which comprises a rim and the spoke, the spoke being formed integrally on the inner periphery of the rim;
the vehicle steering wheel is configured so that the operator grips the proximity of a point of intersection between the rim and a laterally extending side of the substantially T-shaped spoke; and
a line through the areas formed into the concavities or convexities intersects a line at an incline so as progress outward from the bottom to the top, the line extending perpendicularly to the laterally extending side.

6. The switch system of claim 4, wherein:
the switch is a first switch;
the spoke also has a second switch;
the second switch is disposed in an area closer to the rim than the first switch; and
the switch system has a control unit for assessing that only a contact signal of the first switch has been detected when contact signals are simultaneously received from both the first switch and the second switch.

7. The switch system of claim 6, wherein the operation surface of the first switch is tilted to the front in the vehicle body relative to the operation surface of the second switch so as to move away from the finger of the operator.

8. The switch system of claim 1, wherein:
a backlight for illuminating the operation surface of the switch is provided in the proximity of the switch; and
the backlight is turned on by the detection of contact on the switch by the operator.

9. The switch system of claim 1, wherein:
the switch system is attached to a vehicle steering wheel;
the vehicle steering wheel comprises a rim for steering the vehicle and a spoke formed integrally on the inner peripheral surface of the rim;
the operation surface is positioned in an area within the spoke allowing operation while the rim is gripped; and
the operation surface is positioned farther forward in the vehicle body than a plane fanning out from an area where the distal end of the thumb of the operator in a normal driving posture touches the rim;
the axis being a direction orthogonal to the plane of the vehicle steering wheel; and
the center being the area touched by the ball of the thumb of the operator when the operator grips the rim.

10. The switch system of claim 9, wherein the operation surface is inclined forward in the vehicle body from the outer peripheral edge of the rim toward the center.

11. The switch system of claim 9, wherein the operation surface is positioned in a location where the operation surface can be operated by the thumb of the operator while the ball of the thumb is in contact with the rim.
